(19) United States
(12) Patent Application Publication
(10) Pub. No.: US 2006/0044771 A1
(43) Pub. Date: Mar. 2, 2006

(54) Electronic module with conductive polymer

(76) Inventors: Chee Keng Yeo, Singapore (SG); Su Liang Chan, Singapore (SG); Sim Ying Yong, Singapore (SG)

Correspondence Address: DELPHI TECHNOLOGIES, INC., M/C 480-410-202, PO BOX 5052, TROY, MI, 48007, US

(21) Appl. No.: 10/924,452

(22) Filed: Aug. 24, 2004

(51) Int. Cl. H05K 1/18

(52) U.S. Cl. 361/761

(57) ABSTRACT

An electronic module includes a substrate, at least one surface mountable integrated circuit (IC) component and a conductive polymer. The substrate includes a plurality of electrically conductive traces formed on at least one surface of the substrate. The at least one surface mountable integrated circuit component includes a plurality of conductive pads formed on at least a first surface of the component and the conductive pads are electrically coupled to at least one of the conductive traces. The conductive polymer is in contact with at least a portion of a second surface, which is opposite the first surface, of the component and the substrate.

### TECHNICAL FIELD

The present invention is generally directed to an electronic module and, more specifically, to an electronic module that includes a conductive polymer that facilitates improved thermal dissipation and may provide backside electrical contact.

### BACKGROUND OF THE INVENTION

Electronic modules have been widely utilized in the automotive industry and have taken various forms, such as an all silicon ignition (ASI) module implemented in a TO247 package. Typically, such electronic modules have been encapsulated, e.g., with an epoxy mold compound, to seal the electronic components of the module from the environment. In a typical prior art electronic module, an electronic component, e.g., an integrated circuit (IC) die, has been electrically coupled to conductive traces formed on a surface of a substrate through a solder reflow process. In certain applications, backside electrical contact has been made between the die and the substrate through the use of wire bond interconnections. In other prior art electronic modules, backside electrical contact has been achieved with a conductive metal cap. While many electronic module designs generally function adequately in low power applications, these designs may experience problems adequately dissipating heat in higher power applications.

What is needed is a technique that provides an electronic module with improved thermal dissipation. It would also be desirable if the technique readily facilitated backside electrical contact of integrated circuit (IC) dies associated with the electronic module.

### SUMMARY OF THE INVENTION

The present invention is directed to an electronic module that includes a substrate, at least one surface mounted integrated circuit (IC) component and a conductive polymer. The substrate includes a plurality of electrically conductive traces formed on at least a first surface of the substrate. The at least one surface mountable integrated circuit (IC) component includes a plurality of conductive pads, formed on at least a first surface of the component, that are electrically coupled to at least one of the conductive traces. The conductive polymer is in contact with at least a portion of a second surface, which is opposite the first surface, of the component and the substrate.

According to another aspect of the present invention, the electronic module includes an electrically non-conductive overmold material that encapsulates the component, the conductive polymer and at least a portion of the substrate. According to one embodiment, the overmold material is an epoxy molding compound. According to other aspects of the present invention, the conductive polymer may be a thermally conductive polymer and/or an electrically conductive polymer. When the conductive polymer is an electrically conductive polymer, the polymer may be a silver paste that may be readily printed over the component. It should be appreciated that the present invention is applicable to a wide variety of substrates, such as ceramic substrates and printed circuit boards (PCBs) and a wide variety of components, such as flip chips.

These and other features, advantages and objects of the present invention will be further understood and appreciated by those skilled in the art by reference to the following specification, claims and appended drawings.

### BRIEF DESCRIPTION OF THE DRAWINGS

The present invention will now be described, by way of example, with reference to the accompanying drawings, in which:

FIG. 1 is a perspective view of an exemplary overmolded electronic module, configured according to one embodiment of the present invention;

FIG. 2 is a cross-sectional view of a portion of the module of FIG. 1, depicting a conductive polymer that contacts at least a portion of an upper surface of an integrated circuit (IC) die and its associated substrate;

FIG. 3 is a partial flow diagram of an exemplary manufacturing process for producing the module of FIG. 1; and

FIG. 4 is an exemplary chart depicting the decrease of die temperature as the thermal conductivity of a conductive polymer of the module of FIG. 1 is increased.

### DESCRIPTION OF THE PREFERRED EMBODIMENTS

While some electronic module designs have addressed heat dissipation, while simultaneously providing backside electrical connection for integrated circuit (IC) dies associated with the module, such designs have generally not maximized heat dissipation of the module in a relatively economical manner. According to various embodiments of the present invention, a conductive polymer is utilized to enhance thermal dissipation of an electronic module. According to other aspects of the present invention a conductive polymer may also be selected to provide thermal dissipation and backside electrical contact.

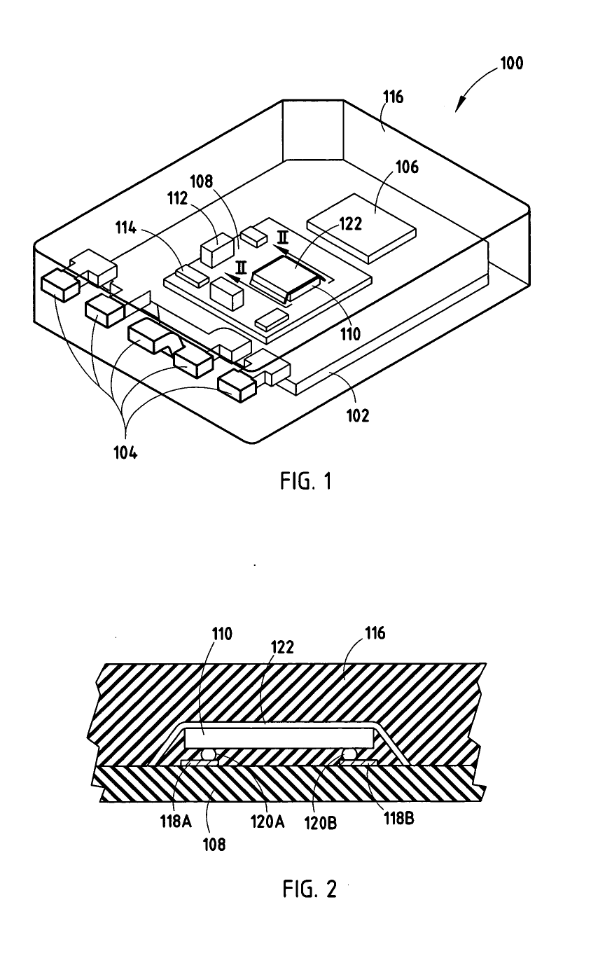

FIG. 1 depicts an exemplary electronic module 100 that includes an electrically conductive tab/header or base plate 102 that may act as a ground plane and be connected to one or more of a plurality of conductive lead pins 104. An electronic component 106, e.g., an integrated circuit (IC) die, that includes circuitry to implement a transistor, such as an insulated gate bipolar transistor (IGBT), may be configured such that a drain of the transistor is brought out on a face of the die 106 coupled to the base plate 102. In this configuration, a gate and source of the transistor are brought out on a face of the die 106 opposite the drain. A substrate 108, such as an alumina substrate, may provide interconnecting paths for a plurality of electronic components, such as a chip capacitor 112 and an application specific integrated circuit (ASIC) 110, and may also provide bond pads 114 for coupling the various associated components of the substrate 108 to one or more of the lead pins 104 and/or to circuitry integrated within the die 106. In a typical such assembly, the electronic components are encased in an epoxy mold compound 116. The epoxy mold compound may serve to seal the electronic components from the environment and may also be utilized to better match a coefficient of thermal expansion (CTE) of the various components located within the assembly 100.

With reference to FIG. 2, a partial cross-sectional view of the module 100 of FIG. 1 is further depicted. As is shown, an overmold material 116 encapsulates the integrated circuit (IC) 110 and at least a portion of the substrate 108. The IC 110 is electrically coupled to traces 118A and 118B associated with the substrate 108 by solder bumps 120A and 120B, respectively. The substrate 108 may take a variety of forms, such as a ceramic substrate and/or a printed circuit board (PCB) formed, for example, from a material, such as FR4. The IC 110 may be, for example, a flip chip or other surface mount technology (SMT) device. According to the present invention, a conductive polymer 122 is deposited on a least a portion of the substrate 108 and the IC 110 to provide backside electrical contact and/or to increase thermal dissipation of the IC 110.

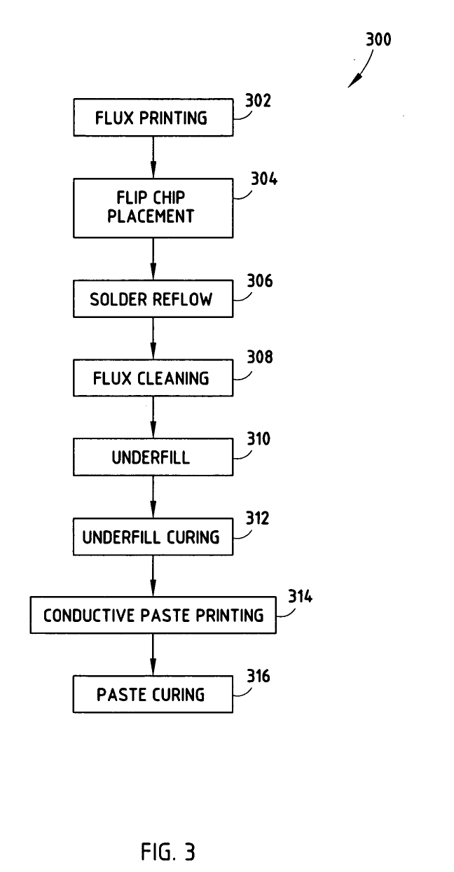

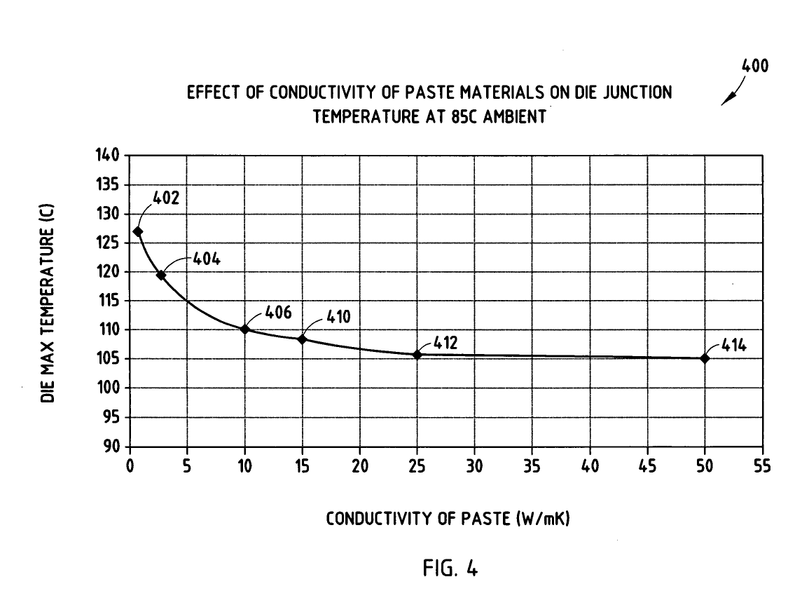

With reference to FIG. 3, a portion of a manufacturing process 300 for producing an electronic module according to the various embodiments of the present invention is depicted. In step 302, the process 300 is initiated by printing flux on the substrate 108. Next, in step 304, various electronic components, e.g., the IC 110, are placed on the substrate 108. Next, in step 306, a solder reflow process is initiated, whereby the solder bumps 120A and 120B (see FIG. 2) are heated to electrically connect the IC 110 to the electrical traces 118A and 118B, respectively. Next, in step 308, a flux cleaning process is initiated, followed by an underfill process in step 310 which underfills the IC 110.

As is well known to those of ordinary skill in the art, underfilling an electrical component prior to overmolding prevents damage to electrical connections that join the component to a substrate. Next, in step 312, the underfill is cured. Then, in step 314, a conductive paste, i.e., the conductive polymer 122, is printed onto a portion of the substrate 108 and a portion of the IC 110. As previously mentioned, the conductive polymer 122 may increase heat transfer from the IC 110 and may also provide backside electrical connection between the IC 110 and the substrate 108. Next, in step 316, the polymer 122 is cured. Following the paste process, the module 100 is then ready for encapsulation.

As is shown in FIG. 4, implementing a conductive paste of 15 W/mK according to the present invention improves a bare die, e.g., flip chip, thermal performance by 19 C/W. Further, use of a thermal paste to perform backside electrical contact can substantially improve the electrical resistance of the bond, as compared to designs that use a wire bond interconnection. It should be appreciated that the printing of the conductive paste over the flip chip can be performed using an existing printing machine and can readily accommodate designs with different die sizes.

With reference again to FIG. 4, a curve 400 that illustrates the relationship between junction temperature of a typical die and conductivity of a conductive polymer positioned to provide a heatsink for the die, as is shown in FIGS. 1 and 2, is depicted. At point 402 the die has a maximum die temperature of approximately 127° C. when the die is in free air at 85° C. At point 404 the maximum temperature of the die is approximately 119° C., when the polymer has a conductivity of 3 W/mK. With reference to point 406, using a polymer having a conductivity of approximately 10 W/mK lowers the maximum die temperature to approximately 110° C. Referring to point 408, using a paste having a conductivity of approximately 15 W/mK lowers the maximum die temperature to approximately 108° C. As is shown, further increasing the conductivity of the paste has a decreasing positive effect on heat dissipation. For example, at point 410 the maximum die temperature is 106° C. when the paste has a conductivity of 25 W/mK. Further, at point 412 the maximum die temperature is 105° C. with a paste conductivity of 50 Watts/mK.

Accordingly, an electronic module has been described herein that exhibits increased thermal performance through the use of conductive polymer. The conductive polymer can also be utilized to provide backside electrical contact when desired.

The above description is considered that of the preferred embodiments only. Modifications of the invention will occur to those skilled in the art and to those who make or use the invention. Therefore, it is understood that the embodiments shown in the drawings and described above are merely for illustrative purposes and not intended to limit the scope of the invention, which is defined by the following claims as interpreted according to the principles of patent law, including the doctrine of equivalents.

1. An electronic module, comprising:
a substrate including a plurality of electrically conductive traces formed on at least a first surface of the substrate;
at least one surface mountable integrated circuit (IC) component including a plurality of conductive pads formed on at least a first surface of the component, wherein the plurality of conductive pads are electrically coupled to at least one of the conductive traces; and
a conductive polymer in contact with at least a portion of a second surface of the component and the substrate, wherein the second surface of the component is opposite the first surface of the component.

2. The module of claim 1, further including:
an electrically non-conductive overmold material encapsulating the component, the conductive polymer and at least a portion of the substrate.

3. The module of claim 2, wherein the overmold material is an epoxy molding compound.

4. The module of claim 1, wherein the conductive polymer is a thermally conductive polymer.

5. The module of claim 1, wherein the conductive polymer is an electrically conductive polymer.

6. The module of claim 1, wherein the conductive polymer is a silver paste.

7. The module of claim 1, wherein the substrate is one of a ceramic substrate and a printed circuit board (PCB).

8. The module of claim 1, wherein the component is a flip-chip.

9. An electronic module, comprising:
a substrate including a plurality of electrically conductive traces formed on at least a first surface of the substrate;
at least one surface mountable integrated circuit (IC) component including a plurality of conductive pads formed on at least a first surface of the component, wherein the plurality of conductive pads are electrically coupled to at least one of the conductive traces; and
a conductive polymer in contact with at least a portion of a second surface of the component and the substrate, wherein the second surface of the component is opposite the first surface of the component and the conductive polymer is a thermally conductive polymer.

10. The module of claim 9, further including:
an electrically non-conductive overmold material encapsulating the component, the conductive polymer and at least a portion of the substrate.

11. The module of claim 9, wherein the overmold material is an epoxy molding compound.

12. The module of claim 9, wherein the conductive polymer is an electrically conductive polymer.

13. The module of claim 12, wherein the conductive polymer is a silver paste.

14. The module of claim 9, wherein the substrate is one of a ceramic substrate and a printed circuit board (PCB).

15. The module of claim 9, wherein the component is a flip-chip.

16. A method for manufacturing an electronic module, comprising the steps of:
providing a substrate including a plurality of electrically conductive traces formed on at least a first surface of the substrate;
providing at least one surface mountable integrated circuit (IC) component including a plurality of conductive pads formed on at least a first surface of the component;
electrically coupling one or more of the conductive pads of the component to at least one of the conductive traces; and
depositing a conductive polymer on at least a portion of the second surface of the component and the substrate.

17. The method of claim 16, further comprising the step of:
encapsulating the component, the conductive polymer and at least a portion of the substrate with an electrically non-conductive overmold material.

18. The method of claim 16, wherein the conductive polymer is at least one of a thermally conductive polymer and an electrically conductive polymer.

19. The method of claim 16, wherein the conductive polymer is a silver paste.

20. The method of claim 16, wherein the substrate is one of a ceramic substrate and a printed circuit board (PCB) and the component is a flip-chip.
